(19) United States
(12) Patent Application Publication
(10) Pub. No.: US 2021/0071292 A1
(43) Pub. Date: Mar. 11, 2021

(54) SINGLE-CRYSTALLINE METAL FILMS

(71) Applicant: FEDERAL STATE BUDGETARY INSTITUTION OF HIGHER PROFESSIONAL EDUCATION "BAUMAN MOSCOW STATE TECHNICAL, Moscow (RU)

(72) Inventors: Ilya Anatolevich RODIONOV, Moscow (RU); Aleksandr Sergeevich BABURIN, Moscow (RU); Ilya Anatolevich RYZHIKOV, Moscow (RU)

(73) Assignee: FEDERAL STATE BUDGETARY INSTITUTION OF HIGHER PROFESSIONAL EDUCATION "BAUMAN MOSCOW STATE TECHNICAL, Moscow (RU)

(21) Appl. No.: 16/958,825

(22) PCT Filed: Jul. 26, 2018
(86) PCT No.: PCT/RU2018/000497

§ 371 Date: Jun. 29, 2020

(30) Foreign Application Priority Data
Dec. 29, 2017 (RU) 2017147005

(51) Int. Cl. C23C 14/18; C23C 14/30; C23C 14/54; C30B 23/06; C30B 29/02

(52) U.S. Cl. CPC C23C 14/18; C23C 14/30; C30B 29/02; C30B 23/063; C23C 14/541

(57) ABSTRACT

According to an example of the present invention, a physical vapour deposition method comprises depositing a metal seed layer on a substrate, wherein the seed layer being deposited under a first temperature of between 20% and 90% of a melting temperature of the metal, and depositing more of the metal on the seed layer at a second temperature, lower than the first temperature, until a continuous single-crystalline film of the metal is complete and has a thickness of 10-2000 nanometres.

### CROSS REFERENCE TO THE RELATED APPLICATIONS

This application is the national phase entry of International Application No. PCT/RU2018/000497, filed on Jul. 26, 2018, which is based upon and claims priority to Russian Patent Application No. 2017147005, filed on Dec. 29, 2017, the entire contents of which are incorporated herein by reference.

### TECHNICAL FIELD

The present invention relates to single-crystalline metal films and physical vapour deposition.

### BACKGROUND

Physical vapour deposition, PVD, methods, are used to produce films and thin coatings. In PVD methods, material is caused to transition from a solid phase to a non-solid phase, from which it may condense back to a condensed phase. The process may be arranged to take place in a vacuum.

Common PVD processes include evaporation and sputtering processes. In the evaporation processes, source material may be evaporated in vacuum or almost vacuum conditions. Evaporation is then the process which causes the source material to transition to non-solid phase, and the evaporated source material is allowed to travel in vacuum to condense on a substrate. Evaporation may be caused to happen by heating the source material.

Sputtering, on the other hand, involves directing particles into the source material at a sufficient energy to dislocate ions or atoms from the source. The thus ejected particles are allowed, in vacuum, to form a film on a target substrate. For example, the particles directed to the source may be ionized and accelerated using an electric field. With a sufficiently strong accelerating field, the energy of the ions is sufficient to eject ions or atoms from the source. The ejected ions or atoms may proceed along a straight trajectory in a vacuum condition, without interacting with a gas before impacting the target substrate, where the ejected ions or atoms may form a crystalline film structure.

Surface plasmon polaritons, SPP, are infrared or visible wavelength electromagnetic waves traveling in an interface between metal and air, or between metal and dielectric. SPPs are a form of surface wave which follow the path of the interface. They tend to have locally high intensity and be spatially confined. SPPs find application in SPP enhanced Raman scattering, on-chip optical interconnects and sub-wavelength waveguides, for example.

Quantum technology is a new field of physics and engineering, which transitions some of the properties of quantum mechanics, especially quantum entanglement, quantum superposition and quantum tunnelling, into practical applications such as quantum computing, quantum sensing, quantum cryptography, quantum simulation, quantum metrology and quantum imaging.

### SUMMARY

According to some aspects, there is provided the subject-matter of the independent claims. Some embodiments are defined in the dependent claims.

According to a first aspect of the present invention, there is provided a physical vapour deposition method comprising depositing a metal seed layer on a substrate, the seed layer being deposited under a first temperature of between 20% and 90% of a melting temperature of the metal, and depositing more of the metal on the seed layer at a second temperature, lower than the first temperature, until a continuous single-crystalline film of the metal is complete, the film having a thickness of 10-2000 nanometres.

Various embodiments of the first aspect may comprise at least one feature from the following bulleted list:
the seed layer is non-continuous
the seed layer comprises flat islands of the metal
the substrate comprises silicon
the substrate comprises sapphire
the substrate comprises diamond
the substrate comprises magnesium oxide
the substrate comprises sodium chloride
the substrate comprises gallium arsenide
the substrate comprises gallium nitride
the substrate comprises indium arsenide
the substrate comprises gallium antimonide
the substrate comprises indium antimonide
the substrate comprises germanium
the substrate comprises cadmium-zinc-telluride
the substrate comprises a mica substrate
the method further comprises annealing the film to reduce a density of defects and to improve film crystalline structure and surface roughness.
the method is performed under vacuum conditions between 1×10⁻⁵ Torr and 1×10⁻¹¹ Torr
the seed layer is deposited in Frank-van-der-Merwe growth mode
the metal comprises silver and the first temperature is in the range of 280 to 420 degrees Celcius
the metal comprises gold and the first temperature is in the range of 320 to 480 degrees Celsius
the metal comprises aluminium the first temperature is in the range of 180 to 330 degrees Celsius
the seed layer is deposited at a deposition rate of 0.05-50 Å/s
the deposition at the second temperature is performed at a deposition rate of 0.05-50 Å/s
the seed layer, when complete, has a weight thickness between 1 and 30 nanometres
islands of the seed layer have top surface with atomically flat characteristic
the film has a film root mean square surface roughness of better than better than 1 nanometre, measured by atomic force microscope in a 90 micrometre by 90 micrometre scan
the film has a film root mean square surface roughness of better than 0.4 nanometres, measured by atomic force microscope in a 2.5 micrometre by 2.5 micrometre scan.

According to a second aspect of the present invention, there is provided a metal thin film structure comprising a substrate with a continuous single-crystalline film of metal thereon, the film having a thickness of 10-2000 nanometres, the film has fewer than 20 voids and pits over an 15×15 mm area, and the film has a film root mean square surface roughness of better than 1 nanometre, measured by atomic force microscope in a 90 micrometre by 90 micrometre scan.

Various embodiments of the second aspect may comprise at least one feature from the following bulleted list:
the metal comprises silver, wherein the silver has ε″, being an imaginary part of a dielectric permittivity directly related to optical looses of less than 0.1 for 370-600 nm wavelength range, and wherein the film of silver has ε″, being an imaginary part of the dielectric permittivity directly related to optical looses of less than 0.3 for 350-850 nm wavelength range
the film has a rocking curve through a single-crystalline metal peak has a full-width-at-half-maximum better than 0.3°
the film has a film root mean square surface roughness of better than 0.4 nanometres, measured by atomic force microscope in a 2.5 micrometre by 2.5 micrometre scan
the substrate comprises silicon
the substrate comprises sapphire
the substrate comprises diamond
the substrate comprises magnesium oxide
the substrate comprises sodium chloride
the substrate comprises gallium arsenide
the substrate comprises gallium nitride
the substrate comprises indium arsenide
the substrate comprises gallium antimonide
the substrate comprises indium antimonide
the substrate comprises germanium
the substrate comprises cadmium-zinc-telluride
the substrate comprises a mica substrate
the metal comprises silver, aluminium or gold.

### BRIEF DESCRIPTION OF THE DRAWINGS

FIG. 1 illustrates an example system in accordance with at least some embodiments of the present invention;

FIG. 2A illustrates an example seed layer (AFM scan);

FIG. 2B illustrates a AFM scan of the silver film surface;

FIGS. 3A-3D show an example sequence of film growth from seed layer in the second phase;

FIG. 4 is a flow graph of a method in accordance with at least some embodiments of the present invention, and

FIG. 5 illustrates a flat top nature of seed layer elements.

### ACRONYMS LIST

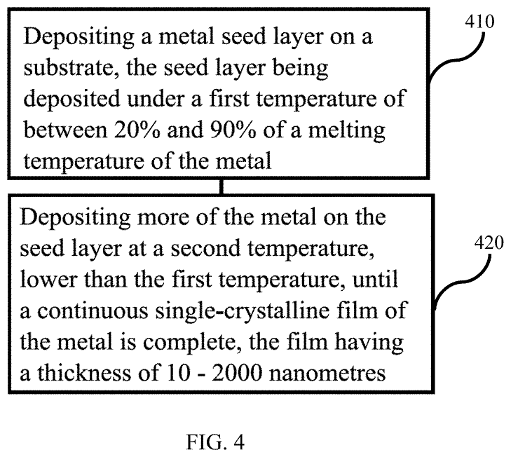

2D two-dimensional
AFM atomic force microscope
AFT atomically flat top
EG electronic growth model
nm nanometre
PVD physical vapour deposition
SEM scanning electron microscope
SPP surface plasmon polariton
QSE quantum size effect

| | |
|---|---|
| 110 | substrate |
| 120 | substrate holder |
| 130 | electron source |
| 140 | source holder |
| 150 | source |
| 160 | electron path |
| 170 | trajectory of evaporated metal |
| 410-420 | phases of the method of FIG. 4 |

### DETAILED DESCRIPTION OF THE EMBODIMENTS

In accordance with embodiments of the present disclosure, methods are disclosed that enable production of flat, continuous, single-crystalline metal films of a thickness of, in general, 10-2000 nanometres, and in some embodiments less than 50 nanometres, for example 10-50 nm. In some embodiments, the film is of less than 200 nm thickness. Also thicker metal films may be obtained. Advantageously, the disclosed methods may be, at least in part, performed under standard high vacuum conditions, by which it is meant the vacuum has a pressure of more than 10⁻⁸ Torr. Thus use of ultra high vacuum conditions is not necessary. By ultra high vacuum it is meant a pressure of less than 10⁻⁹ Torr. Nevertheless, the disclosed methods may also be performed under ultra high vacuum conditions. By continuous, single-crystalline metal films it is herein meant films with fewer than 20 voids and pits over an 15×15 mm area. In some embodiments, there are fewer than 10 voids and pits over the 15×15 mm area. By fewer than 20 voids and pits it is meant that the total number of voids and pits added together is less than 20. Voids and pits are examples of defects.

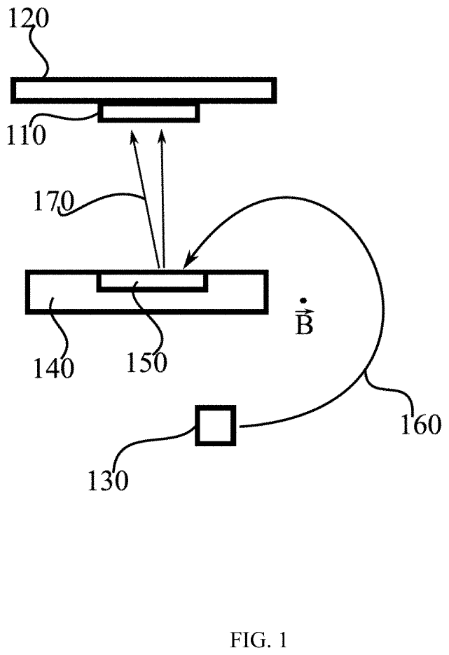

FIG. 1 illustrates an example system in accordance with at least some embodiments of the present invention. The illustrated system is based on electron beam PVD, although the invention is not limited to this specific technology and electron beam PVD is used here merely as an example. Other example PVD technologies include magnetron sputtering, ion beam deposition, thermal evaporation, cathodic arc deposition and pulsed laser deposition.

In use, a substrate 110 is affixed to a substrate holder 120. The substrate may comprise a crystalline substrate, for example Si(111) crystalline silicon. Si(111) refers to a specific set of atomic planes in silicon crystal structure. A Si(111) surface corresponds to a silicon surface parallel to these planes. Alternatively to silicon, the substrate may comprise sapphire, diamond, magnesium oxide, sodium chloride, gallium arsenide, gallium nitride, indium arsenide, gallium antimonide, indium antimonide, germanium, cadmium-zinc-telluride or a mica substrate, for example. Substrate holder 120 may be configured to heat substrate 110 to a desired temperature, for example. Substrate holder 120 may be enabled to manipulate substrate 110 by moving and/or rotating, for example, to expose selected parts thereof to the PVD process.

Electron source 130 emits electrons as a beam, accelerated to a suitable energy, the beam being directed using a magnetic field B along an electron path 160 to source 150, which may comprise niobium, aluminium, silver or gold, for example. In some embodiments, the path of the electron beam may be a straight line, in case a magnetic field B is not used. Electron source 130 may generate the electron beam using the thermionic emission or the anodic arc technique, for example. Source 150 may comprise a bar of the source material, for example. Source 150 may be provided on source holder 140, for example. The electrons incident on source 150 heat the source, which causes melting and/or sublimating of the source material, resulting in evaporation of source material.

The evaporated source material proceeds in vacuum conditions along trajectories 170 to the substrate 110. Once on the substrate, the evaporated source material reverts to solid form, thereby depositing a film on the surface of substrate 110. The substrate may be cleaned prior to the deposition, for example using ultrasound. Substrate 110 may be heated for the duration of the deposition, to enhance diffusion of atoms of source material along the surface of substrate 110, or along a surface of a film being deposited on substrate 110. An atom lying on a crystal surface can be referred to as an adatom, which is abbreviated from “adsorbed atom”. Source material arriving at substrate 110 may initially be adatoms moving along the surface of substrate 110 or along the emerging film, before they find a place on the surface of the film or substrate. On the other hand, if a rough deposited film surface is desired, substrate 110 may be cooled, instead of heated, to reduce diffusion of adatoms.

Different optoelectronic devices have been discussed recently, which are based on the possibility to control light using surface plasmon polaritons, SPPs. Until now the SPP has been considered a relevant instrument to achieve extreme light confinement for practical applications, such as subwavelength waveguides and on-chip optical interconnects, low-threshold continuous-wave operation nanolaser and single-photon quantum emitters, new ultra sensitive applications in biosensing and environmental sensing, photon-plasmon and plasmon-photon modulators, photovoltaic, metamaterials, and others. Losses in metals and suitability for mass production represent the most serious challenges to progress and mass adoption of the afore-mentioned nanophotonics devices.

Substrate-metal configuration and device patterning techniques are connected to each other, as optical properties of the system may dramatically degrade during manufacturing of nanostructures. Thus far, silver, Ag, has been the preferred plasmonics material due to its low losses and SPP propagation length among metals in general at optical and near-IR frequencies. ^{[1]} Moreover, numerical research has shown that from a loss point of view silver remains superior to new alternative plasmonic materials, including graphene.^{[1]} That is why sub-50 nm continuous ultra-flat single-crystalline silver film technology development plays a key role in boosting device performance and could revitalize plasmonics itself.

From the other hand such a metals like aluminium, niobium and others are widely used in quantum technologies where quantum systems Q-factor and coherence are of a key importance to build new practical quantum devices for quantum communication, computing, sensing and simulation applications. Single-crystalline metal films technology development using mass production compatible methods is therefore of importance.

Stable, reproducible technology for repeatable producing sub-50 nm continuous ultra-flat single-crystalline metal films by means of standard high vacuum technological equipment is of significant utility. This would enable avoiding the use of ultra-high vacuum tools, which are cumbersome and expensive. As silver is one of the most difficult metals for sub-50 nm thick single-crystalline growth because of its high chemical instability, lattice-matched substrates dewetting at elevated temperature^{[2]} and high reactivity^{[3]} in the present disclosure silver on silicon, at different orientations, are used as examples. Mica substrates may also be used. Use of other metals, including gold, and other substrates are also possible in the context of principles of the present invention. So far, without the benefit of the present invention, gold single-crystalline films have only been created at thicknesses of at least 80 nanometres. Obtaining a thin, sub-50 nm film is beneficial also in that it enables construction of smaller-scale nanostructures, for example ones which use SPPs.

A two-step process is herein described for growing, by deposition, flat single-crystalline metal films. The films may have a thickness of over 10 nm, for example between 10 and 2000 nm. A further example is 10-50 nm. An even further example is 10-200 nm. By single-crystalline it is meant that a crystal lattice of the metal film is continuous and unbroken without grain boundaries. The two steps may be completed in vacuum conditions where the pressure is between 10⁻⁵ Torr and 10⁻¹¹ Torr, in other words, an ultra-high vacuum condition of at least 10⁻⁹ Torr is not necessary. For example, the vacuum condition may be between 10⁻⁵ Torr and 10⁻⁸ Torr.

In a first step, a seed layer is deposited on the substrate. The first step takes place at an elevated temperature. By elevated temperature it is meant that the substrate 110 is at the said elevated temperature. This elevated temperature is selected in dependence of the source metal, in general it may be said to lie between 20% and 90% of a melting temperature of the source metal. Further example ranges are between 30% and 80%, between 25% and 45% and between 20% and 50% of the melting temperature of the source metal. These percentages are to be calculated from the Celsius values of melting point under normal conditions. For example silver under normal conditions has a melting point of 961.9° C., whereof 20% is 192.38° C. and 90% is 865.71° C. The seed layer may be non-continuous, comprising, for example, plural distinct elements of seed layer which partly, but not completely, cover the substrate. Such elements will be referred to as or “islands” in the following. The seed layer may comprise atomically flat top, AFT, islands.

For a second step, the temperature is allowed to cool, for example to room temperature. Once the temperature has cooled, depositing the source metal is resumed and continued until the seed layer has been transformed into a continuous metal film of predefined thickness.

The two-step method results in thin single-crystalline films with good characteristics, such as an absence of voids and pits, limited roughness, good dielectric permittivity and a crystalline structure measured by means of X-Ray diffractometry, XRD, such that a rocking curve through the single-crystalline metal peak has a full-width-at-half-maximum (FWHM) better than 0.3°, indicative of a low mosaic spread in the film. In fact, the single-crystalline film thickness with 100% continuity, surface roughness and dielectric permittivity characteristics of the single-crystalline metal films obtained by the herein disclosed method are better than those reported in thin metal films obtained previously even using ultra high vacuum conditions. Consequently a technical effect is provided with respect to these methods in that the surface roughness and dielectric permittivity characteristic is improved and a stable continuous single-crystalline metal film with the thickness down to 10 nm could be fabricated.

It is believed the improvements in film characteristics thus obtained rely on a combination of two mixed evaporation modes partially controlled by quantum sized effects. The method may further comprise a third step, wherein the film is annealed to reduce a density of defects and to improve further improve surface smoothness.

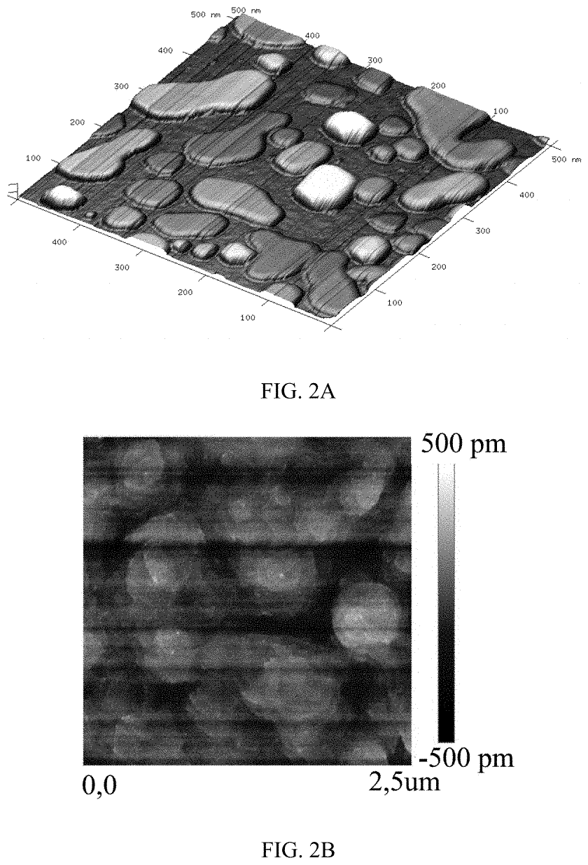

FIG. 2A illustrates an example seed layer where the metal is silver. The axes denote distances in nanometres, nm. As can be seen, the seed layer is in this example discontinuous and comprised of flat islands of the metal that will form the film. The islands can be characterized as having an atomically flat top surface.

FIG. 2B illustrates a atomic force microscope, AFM, scan of a fabricated silver 35 nm-thick film which illustrates the root mean square, RMS, roughness as less than 100 picometres, pm, measured over an 2.5 um×2.5 um area.

The first step of the process results, as illustrated in FIG. 2A in atomically flat-top, AFT, two dimensional, 2D, Ag(111) islands of a seed layer. Most of the islands, for example more than 70% of all the islands, are of almost the same height. Using the Frank van der Merwe growth mode, also known as layer-by-layer 2D growth, may be used to explain the process of generating AFT 2D islands of same height. A preferably AFT 2D island may occur when twice the surface energy of the overlaying silver film is lower than the adhesion energy of the silver film to the Si substrate^{[4]}. Twice the surface energy of silver corresponds to the adhesion energy of silver to silver, so this criterion amounts to a direct comparison of different adhesion energies. Adhesion energy may include a strain contribution^{[4]}. Based on experiments, the inventors have found that there is a temperature range which corresponds to Frank van der Merwe growth mode, when most of the 2D islands will be of the same height.

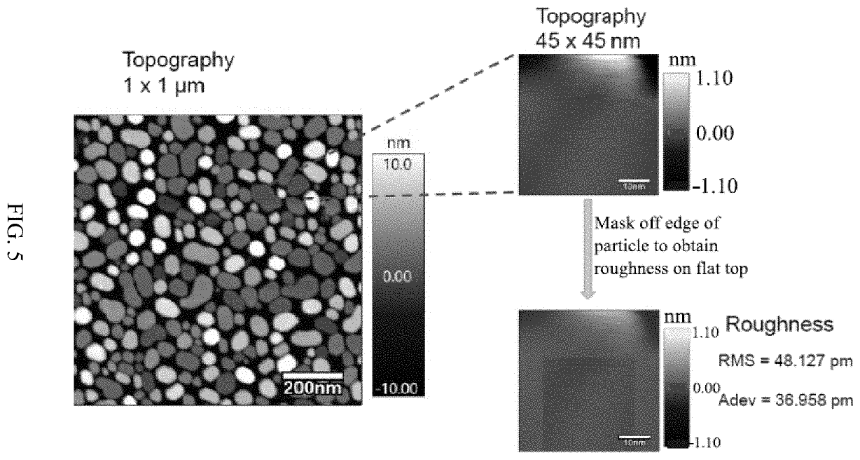

FIG. 5 illustrates a flat top nature of seed layer elements. The RMS roughness is 48.127 picometres over an example seed layer element top.

Growth mode of the film and Ag—Si(111) system conditions are strongly influenced by substrate temperature, deposition rate and layer thickness. The inventors have found that AFT 2D Ag(111) seed islands can be grown under the following conditions: 280-420° C. temperature, 0.5-10 Å/s deposition rate and weight thickness of 1-25 nm. The weight thickness may be determined, for example, using a quartz rate monitor. One may determine the conditions of AFT 2D seed islands growth for different metal-substrate systems. The inventors have found that AFT 2D Au(111) seed islands can be grown under the following conditions: 320-480° C. temperature, 0.1-5 Å/s deposition rate and weight thickness of 1-25 nm. The inventors have found that AFT 2D Al(111) seed islands can be grown under the following conditions: 180-330° C. temperature, 0.5-10 Å/s deposition rate and weight thickness of 1-25 nm.

For each of Ag, Au and Al, and indeed for other metals, the film thickness may be between 10-2000 nm, for example 10-50 nm or 10-40 nm. By weight thickness it is meant weight which is measured by a quarz rate monitor.

AFT 2D Ag(111) two-dimensional islands of the first step may, as discussed above, have a predefined height, an atomically flat top surface and a crystalline structure which affect the rest of the process. This is so, since these parameters define an epitaxial-like nature of the film growth on the second step. An electronic growth model, EG, based on the quantum size effect, QSE, ^{[5]} may explain the nature of silver AFT 2D seed layer growth on a Si(111) substrate, for example. QSE may also be referred to as quantum confinement effects, which describe system behavior in terms of energy levels, potential wells, valence bands, conduction bands and energy band gaps. The EG model may help to explain three key properties of an ideal AFT 2D seed layer: firstly, the AFT 2D island seed layer has an optimal thickness. Secondly, the possibility to grow an AFT 2D islands of predefined height and orientation, and thirdly, an additional surface energy which could be accumulated in AFT 2D islands induced by the islands' internal stress.

According to the EG model, an electron gas is confined to a two-dimensional quantum well as wide as the thickness of the silver islands. ^{[6]} The energy oscillates as a function of the island thickness. At larger thicknesses, such as thicker than 5-10 monolayers or after so called inter-mixing layer, the oscillation magnitude decreases, and it coincides with the Fermi energy for a bulk Ag crystal, E_{f}. Upon this thickness the top silver layers of the islands grow without any contact with the substrate in the homoepitaxial regime, usually resulting in an island height preference which is quantized,^{[6]} forming an ideal seed layer even for non-ideally lattice-matched substrates even with standard deposition tool process parameters deviations. Thus it is advantageously possible to form an ideal seed layer for growing a single-crystalline metal film using a standard cleanroom and standard tools. This works for many metals and substrates.

After first step an AFT 2D island seed forms a layer of islands with the preferred mean island diameter being in the range 100-250 nm, and island-to-island distance in the range of 2-50 nm. The islands may have irregular form and wetting the substrate very well. Such islands are illustrated in FIG. 2A. There is an optimal AFT 2D island height which on the one hand provides a dislocation-free crystalline lattice Ag(111) island growth and, on the other hand at this height an ultimate initial stress is accumulated in the seed islands as a result of strained growth under high temperature. Strained growth is induced by starting screw dislocation influence and spiral growth. Both factors play a role in the process described herein. The presence of screw dislocation and spiral growth limits the maximum height of ideal islands in the seed layer. In a similar manner, it can be shown that for each metal, AFT 2D island seeds have a predefined optimal thickness.

When moving to the second step, evaporation of the source material is stopped, the substrate is allowed to cool down under the same vacuum conditions as were used in the first step, for example all the way to room temperature. Then, the AFT 2D islands seed are converted to a continuous planar film layer with a deposition rate of 0.05-50 Å/s, or alternatively 0.5-3 Å/s, for example. The second deposition step, which may proceed in a 2D growth mode, results in a fully continuous single-crystalline silver film without voids and pits. During the second step, almost all the new adatoms arriving at the substrate take their places on a perimeter edge of AFT 2D islands, eventually joining the islands to each other and thus completing the single-crystalline thin film.

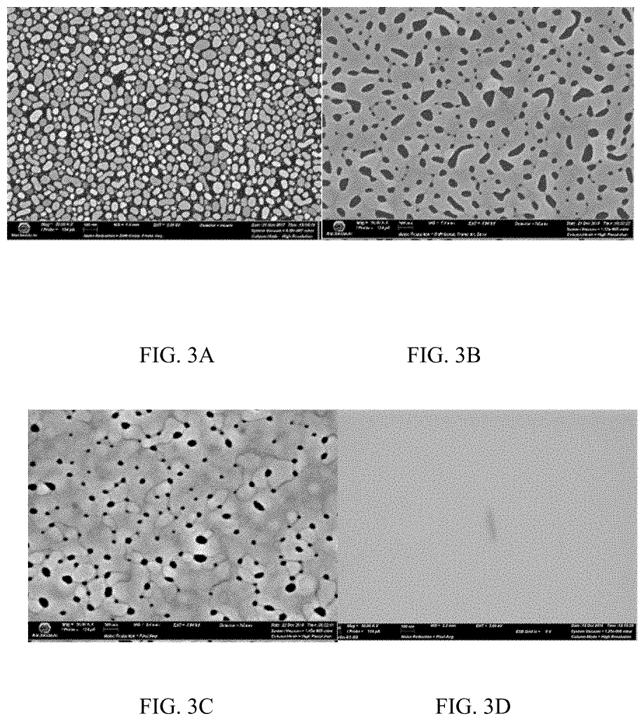

FIGS. 3A-3D show an example sequence of film growth in the second step, from ideal AFT 2D islands seed to a fully continuous film at room temperature. By ideal, it is meant ideal or close enough to ideal to result in an eventual film that fulfils the quality requirements set out herein, that is, it is continuous and single-crystalline. FIG. 3A illustrates the initial AFT 2D islands seed layer. In FIG. 3B, the ideal seed layer has been deposited with more 10 nm weight thickness silver. In FIG. 3C, the «ideal» seed layer has been deposited with more 20 nm (weight thickness) silver. In FIG. 3D, the ideal seed layer has been deposited with more 30 nm weight thickness silver and annealed. As can be seen from FIGS. 3A-3D, as the deposition progresses in the second step, gaps between the seed islands become progressively smaller as the islands grow into each other, ultimately resulting in a fully continuous metal film.

The defect visible in FIG. 3D on the film surface has been made purposefully, by burning with a scanning electron microscope SEM electron beam, to facilitate focusing the SEM on the surface of the atomically flat film.

In the second step, due to reduced Ag adatom energy and surface diffusion length, ^{[7]} the 2D islands of dominant Ag(111) orientation become progressively larger in size. The surface diffusion length is reduced by the reduced temperature of the substrate, when compared to the first step. Ag adatoms are caused to hop along the atomically flat top surfaces of the 2D seed islands with almost no energy dissipation, whereby adatom surface diffusion length becomes comparable to a mean diameter of the seed islands. Seed islands crystalline lattice genesis may, in the second step, additionally use relaxation of energy accumulated during the first step. ^{[8]} These factors may increase the probability of dominant Ag(111) AFT 2D island growth. At room temperature, as a result of reduced Ag adatom mobility, the adatoms relax at the island perimeter when they reach seed island edges. This overcomes the potential barrier on the edges by means of intrinsic energy and stress relaxation. By stress it is meant the energy accumulated in islands during first growing step. In the second growth step, a number of desirable film crystalline structure changes take place simultaneously: firstly, negative stress energy accumulated during the first growing step relaxes primarily to interaction with adatoms on the island edges, improving the crystalline structure of AFT 2D islands by stress relaxation. Secondly, almost all the incoming adatoms are absorbed on the island edges. Thirdly, 2D growth mode provides a fully continuous film formation starting from 10 nm thickness, and finally, the thus formed fully continuous film is dominantly in the Ag(111) orientation.

Second step parameter optimization enables forming Ag(111) 2D island spreading similarly to a solid phase epitaxy process, toward a fully continuous film, but in less demanding vacuum conditions. Upon subsequent annealing, for example at a temperature higher than that used in the first step, the crystalline growth is finished, defect density reduced and surface roughness improved. The inventors have found that annealing for silver may be performed in the range of 320-480° C., for gold at 350-550° C. and for aluminium at 250-450° C., for example. As the result of process parameter optimization the inventors have demonstrated fully continuous silver film growth with a thickness as low as 10 nm.

Using the herein disclosed technology, the inventors have experimentally demonstrated solving the problem of substrate surface silver dewetting for sub-50 nm single-crystalline silver film deposition. By dewetting it is meant a process where a film on a substrate is ruptured, leading to formation of droplets. Using the disclosed process, a thin single-crystalline metal film may be deposited in just several hours using standard high vacuum deposition tools which has a substrate heating option.

In general, there is provided a physical vapour deposition method comprising depositing a metal seed layer on a substrate, the seed layer being deposited under a first temperature of between 20% and 90% of a melting temperature of the metal and first deposition rate of between 0.05 and 50 Å/s, and depositing more of the metal on the seed layer with the second deposition rate of between 0.05 and 50 Å/s at a second temperature, lower than the first temperature, until a continuous single-crystalline film of the metal is complete, the film having a thickness of 10-2000 nanometres. The temperatures may refer to temperatures of a substrate onto which the continuous single-crystalline film of the metal is built by the method.

The two steps of deposition may be completed in vacuum conditions where the pressure is between 10⁻⁵ Torr and 10⁻¹¹ Torr. The pressure may be higher than 10⁻⁹ Torr. The seed layer may be deposited in 2D growth mode, for example in Frank-van-der-Merwe growth mode. The metal may comprise silver, and the first temperature may be in the range of 280 to 420 degrees Celcius. The seed layer may be, when complete, between 1 and 30 nm thick. By thickness of the seed layer, it may be meant that weight thickness measured by a quartz thickness monitor of the deposition tool, for example. The elements the seed layer may comprise atomically flat top elements, such as, for example, atomically flat top islands.

The film may have a surface roughness of better than 0.1 nanometres, measured by atomic force microscope in a 2.5 micrometre by 2.5 micrometre scan, for example. On the other hand, the film may have a film roughness of better than 0.5 nanometres, measured by atomic force microscope in a 90 micrometre by 90 micrometre scan. Where the annealing step is present, film roughness may be reduced, that is, improved, compared to a variant of the method where the annealing is not performed.

In general, annealing is a heat treatment that alters physical properties of a material, such as a metal. Annealing may comprise heating a material, such as the metal of the single-crystalline film, to above its recrystallization temperature, maintaining a suitable temperature, and the cooling. The recrystallization temperature of silver is, in general, between 320 and 480 degrees centigrade.

FIG. 4 is a flow graph of a physical vapour deposition method in accordance with at least some embodiments of the present invention.

Phase 410 comprises depositing a metal seed layer on a substrate, the seed layer being deposited under a first temperature of between 20% and 90% of a melting temperature of the metal and first deposition rate. The temperature may be here expressed in terms of degrees Celsius. The temperature may be a temperature of the substrate. The substrate may comprise silicon, sapphire, diamond, magnesium oxide, sodium chloride, gallium arsenide, gallium nitride, indium arsenide, gallium antimonide, indium antimonide, germanium, cadmium-zinc-tellur or a mica, for example. Phase 420 comprises depositing more of the metal on the seed layer with second deposition rate at a second temperature, lower than the first temperature, until a continuous single-crystalline film of the metal is complete, the film having a thickness of 10-2000 nanometres.

It is to be understood that the embodiments of the invention disclosed are not limited to the particular structures, process steps, or materials disclosed herein, but are extended to equivalents thereof as would be recognized by those ordinarily skilled in the relevant arts. It should also be understood that terminology employed herein is used for the purpose of describing particular embodiments only and is not intended to be limiting.

Reference throughout this specification to one embodiment or an embodiment means that a particular feature, structure, or characteristic described in connection with the embodiment is included in at least one embodiment of the present invention. Thus, appearances of the phrases “in one embodiment” or “in an embodiment” in various places throughout this specification are not necessarily all referring to the same embodiment. Where reference is made to a numerical value using a term such as, for example, about or substantially, the exact numerical value is also disclosed.

As used herein, a plurality of items, structural elements, compositional elements, and/or materials may be presented in a common list for convenience. However, these lists should be construed as though each member of the list is individually identified as a separate and unique member. Thus, no individual member of such list should be construed as a de facto equivalent of any other member of the same list solely based on their presentation in a common group without indications to the contrary. In addition, various embodiments and example of the present invention may be referred to herein along with alternatives for the various components thereof. It is understood that such embodiments, examples, and alternatives are not to be construed as de facto equivalents of one another, but are to be considered as separate and autonomous representations of the present invention.

Furthermore, the described features, structures, or characteristics may be combined in any suitable manner in one or more embodiments. In the preceding description, numerous specific details are provided, such as examples of lengths, widths, shapes, etc., to provide a thorough understanding of embodiments of the invention. One skilled in the relevant art will recognize, however, that the invention can be practiced without one or more of the specific details, or with other methods, components, materials, etc. In other instances, well-known structures, materials, or operations are not shown or described in detail to avoid obscuring aspects of the invention.

While the forgoing examples are illustrative of the principles of the present invention in one or more particular applications, it will be apparent to those of ordinary skill in the art that numerous modifications in form, usage and details of implementation can be made without the exercise of inventive faculty, and without departing from the principles and concepts of the invention. Accordingly, it is not intended that the invention be limited, except as by the claims set forth below.

The verbs “to comprise” and “to include” are used in this document as open limitations that neither exclude nor require the existence of also un-recited features. The features recited in depending claims are mutually freely combinable unless otherwise explicitly stated. Furthermore, it is to be understood that the use of “a” or “an”, that is, a singular form, throughout this document does not exclude a plurality.

At least some embodiments of the present invention find industrial application in physical vapour deposition, for example.

### CITATION LIST

[1] B. Dastmalchi, P Tassin, T. Koschny, C. M. Soukoulis. Adv. Opt. Mater., 2016, 4, 171.
[2] S. Kunwar, M. Sui, Q. Zhang, P. Pandey, M.-Y. Li, J. Lee, Nano-Micro Lett. 2017, 9 (2), 17.
[3] K. M. McPeak, S. V. Jayanti, S. J. P. Kress, S. Meyer, S. Iotti, A. Rossinelli, D. J. Norris, ACS Photonics 2015, 2, 326
[4] R. Kern, G. Le Lay, J. J. Metios, 1979, Curr. Top. Mater Sci., 3, 131.
[5] W. B. Su, S. H. Chang, W. B. Jian, C. S. Chang, L. J. Chen, T. T. Tsong, Phys. Rev. Lett. 2001, 86, 5116.
[6] P. Czoschke, H. Hong, L. Basile, T.-C. Chiang, Phys. Rev. B 2005, 72, 075402.
[7] J. Vrijmoeth, H. A. van der Vegt, J. A. Meyer, E. Vlieg, R. J. Behm, Phys. Rev. Lett. 1994, 72, 3843.
[8] F. Sette, T. Hashizume, F. Comin, A. A. MacDowell, and P. H. Citrin, Phys. Rev. Lett. 1988, 61, 1384.

What is claimed is:

1. A physical vapour deposition method comprising:
depositing a metal seed layer of a metal on a substrate, wherein the seed layer is deposited under a first temperature of between 20% and 90% of a melting temperature of the metal, and
depositing more of the metal on the seed layer at a second temperature lower than the first temperature, until a continuous single-crystalline film of the metal is complete, the film having a thickness of 10-2000 nanometres.

2. The method according to claim 1, wherein the seed layer is non-continuous.

3. The method according to claim 2, wherein the seed layer comprises flat islands of the metal.

4. The method according to claim 1, wherein the substrate comprises at least one of the following: silicon, sapphire, diamond, magnesium oxide, sodium chloride, gallium arsenide, gallium nitride, indium arsenide, gallium antimonide, indium antimonide, germanium, cadmium-zinc-telluride or a mica substrate.

5. The method according to claim 1, further comprising annealing the continuous single-crystalline film to reduce a density of defects and to improve a film crystalline structure and surface roughness.

6. The method according to claim 1, wherein the method is performed under vacuum conditions between 1×10⁻⁵ Torr and 1×10⁻¹¹ Torr.

7. The method according to claim 1, wherein the seed layer is deposited in Frank-van-der-Merwe growth mode.

8. The method according to claim 1, wherein one of the following applies:
the metal comprises silver and the first temperature is in the range of 280 to 420 degrees Celcius;
the metal comprises gold and the first temperature is in the range of 320 to 480 degrees Celsius, and
the metal comprises aluminium the first temperature is in the range of 180 to 330 degrees Celsius.

9. The method according to claim 8, wherein the seed layer is deposited at a deposition rate of 0.05-50 Å/s.

10. The method according to claim 1, wherein the deposition at the second temperature is performed at a deposition rate of 0.05-50 Å/s.

11. The method according to claim 1, wherein the seed layer, when complete, has a weight thickness between 1 and 30 nanometres.

12. The method according to claim 1, wherein islands of the seed layer have top surface with atomically flat characteristic.

13. The method according to claim 1, wherein the continuous single-crystalline film has a film root mean square roughness of better than 1 nanometres, measured by an atomic force microscope in a 90 micrometre by 90 micrometre scan.

14. The method according to claim 1, wherein the continuous single-crystalline film has a film root mean square surface roughness of better than 0.4 nanometres, measured by an atomic force microscope in a 2.5 micrometre by 2.5 micrometre scan.

15. A metal thin film structure, comprising:
a substrate with a continuous single-crystalline film of metal thereon, wherein the continuous single-crystalline film has a thickness of 10-2000 nanometres;
the continuous single-crystalline film has fewer than 20 voids and pits over an 15×15 mm area, and
the continuous single-crystalline film has a film root mean square surface roughness of better than 1 nanometre, measured by atomic force microscope in a 90 micrometre by 90 micrometre scan.

16. The thin film structure according to claim 15, wherein the metal comprises silver, wherein the silver has ε″ and ε″ is an imaginary part of a dielectric permittivity directly related to optical looses of less than 0.1 for 370-600 nm wavelength range, and wherein the continuous single-crystalline film of silver has ε″ and ε″ is an imaginary part of the dielectric permittivity directly related to optical looses of less than 0.3 for 350-850 nm wavelength range.

17. The thin film structure according to claim 15, wherein a rocking curve through a single-crystalline metal peak has a full-width-at-half-maximum better than 0.3°.

18. The thin film structure according to claim 15,
wherein the continuous single-crystalline film has a film root mean square surface roughness of better than 0.4 nanometres, measured by an atomic force microscope in a 2.5 micrometre by 2.5 micrometre scan.

19. The thin film structure according to claim 15, wherein the substrate comprises at least one of the following: silicon, sapphire, diamond, magnesium oxide, sodium chloride, gallium arsenide, gallium nitride, indium arsenide, gallium antimonide, indium antimonide, germanium, cadmium-zinc-telluride or a mica substrate.

20. The thin film structure according to claim 15, wherein the metal comprises silver, aluminium or gold.
